(19) United States
(12) Patent Application Publication
(10) Pub. No.: US 2006/0249773 A1
(43) Pub. Date: Nov. 9, 2006

(54) Semiconductor device having high dielectric constant material film and fabrication method for the same

(76) Inventor: Tetsuya Kai, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/335,659

(22) Filed: Jan. 20, 2006

(30) Foreign Application Priority Data
Jan. 26, 2005 (JP) P2005-018415

(51) Int. Cl. H01L 29/94

(52) U.S. Cl. 257/301

(57) ABSTRACT

A semiconductor device fabrication method includes: depositing one of a polycrystal, an amorphous and a compound complex of the polycrystal and the amorphous, including at least one of silicon and germanium on a single-crystal silicon region; depositing a high dielectric constant material film on the semiconductor film; annealing the high dielectric constant material film at a temperature of 700 degrees Centigrade or greater; and depositing an electrode film on the high dielectric constant material film.

### CROSS REFERENCE TO RELATED APPLICATIONS AND INCORPORATION BY REFERENCE

This application is based upon and claims the benefit of priority from the prior Japanese Patent Applications No. P2005-018415, filed on Jan. 26, 2005; the entire contents of which are incorporated herein by reference.

### BACKGROUND OF THE INVENTION

1. Field of the Invention

The present invention relates to a semiconductor device having a high dielectric constant material film and a fabrication method for the same.

2. Description of the Related Art

In recent years, a DRAM, which is a semiconductor device using a high dielectric constant material film as a capacitor/insulator film has been studied. The high permittivity dielectric film, such as an aluminum oxide (Al₂O₃) film, is provided within deep trenches. Use of a high dielectric constant material film as a capacitor/insulator film provides capacitors with a large capacitance and/or small-sized capacitors. However, since a DRAM, using such a high dielectric constant material film as a capacitor/insulator film, tends to have capacitors with a large amount of leakage current, and charging capacitors may be difficult. In addition to a DRAM, the problem of a leakage current may develop in the case of using a high dielectric constant material film as an oxide film of MOSFET gates.

### BRIEF SUMMARY OF THE INVENTION

An aspect of the present invention inheres in a semiconductor device including a plate electrode region made of a single-crystal silicon; a semiconductor film made of one of a polycrystal, an amorphous and a compound complex of the polycrystal and the amorphous, arranged on the plate electrode region, the semiconductor film including at least one of silicon and germanium; a high dielectric constant material film formed on the semiconductor film; and an electrode formed on the high dielectric constant material film.

Another aspect of the present invention inheres in a semiconductor device fabrication method including: depositing a semiconductor film made of one of a polycrystal, an amorphous and a compound complex of the polycrystal and the amorphous, the semiconductor film including at least one of silicon and germanium on a single-crystal silicon region; depositing a high dielectric constant material film on the semiconductor film; annealing the high dielectric constant material film at a temperature of 700 degrees Centigrade or greater; and depositing an electrode film on the high dielectric constant material film.

Another aspect of the present invention inheres in a semiconductor device having a stacked gate structure which includes a semiconductor film made of one of a polycrystal, an amorphous and a compound complex of the polycrystal and the amorphous, the semiconductor film including at least one of silicon and germanium; a high dielectric constant material film formed on the semiconductor film; a floating gate electrode formed on the high dielectric constant material film; an inter-gate insulator film formed on the a floating gate electrode; a control gate electrode formed on the inter-gate insulator layer.

### BRIEF DESCRIPTION OF THE DRAWINGS

FIG. 1 shows a cross sectional view of a semiconductor device according to a first embodiment of the present invention;

FIGS. 2 through 8 show cross sectional views of the semiconductor device during a semiconductor device fabrication process according to the first embodiment.

FIG. 9 is a graph showing a relationship between temperature for heat treatment and leakage current density of a high dielectric constant material film during a semiconductor device fabrication process according to the first embodiment;

FIG. 10 shows a cross sectional view of a semiconductor device according to a second embodiment;

FIG. 11 shows a cross sectional view of a semiconductor device during a semiconductor device fabrication process according to the second embodiment;

FIG. 12 shows a cross sectional view of a semiconductor device according to a third embodiment;

FIG. 13 shows a cross sectional view of the semiconductor device during a semiconductor device fabrication process according to the third embodiment;

FIG. 14 shows a cross sectional view of a semiconductor device according to a fourth embodiment; and

FIGS. 15 through 17 show cross sectional views of the semiconductor device during a semiconductor device fabrication process according to the fourth embodiment.

FIG. 18 is a schematic aerial pattern diagram of a NAND nonvolatile semiconductor memory according to the fifth embodiment of the present invention;

FIG. 19 is a schematic device cross-sectional diagram cut along the line IV-IV of FIG. 18.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

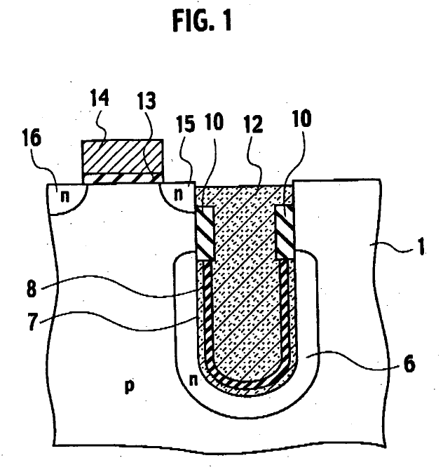

As shown in FIG. 1, a semiconductor device according to the first embodiment of the present invention comprises a silicon substrate 1, a plate electrode region 6, a semiconductor film 7, a high dielectric constant material film 8, an electrode 12, a collar oxide film 10, source and drain regions 15 and 16, a gate insulating film 13, and a gate electrode 14. The semiconductor device of the first embodiment is a DRAM that uses the high dielectric constant material film 8 as a capacitor/insulator film. The DRAM includes a capacitor in a deep trench. The DRAM includes a selector transistor connected to the capacitor.

The silicon substrate 1 may be a p-type single-crystal silicon substrate. The deep trench is formed in the silicon substrate 1.

The plate electrode region 6 may be single-crystal silicon. The conductivity type of the plate electrode region 6 is different from the silicon substrate 1 and is an n type conductivity. A dopant may be arsenic (As) or phosphorus (P). The plate electrode region 6 is formed in the single-crystal silicon substrate 1 so that the plate electrode region 6 includes part of the surface of the silicon substrate 1. The plate electrode region 6 is formed to include part of the surface of the deep trench. The capacitor comprises the high dielectric constant material film 8, which serves as a capacitor/insulator film, and a plate electrode 6 and a charging electrode 12, respectively provided on either side of the capacitor/insulator film 8. The plate electrode region 6 serves as a plate electrode.

The semiconductor film 7 is formed on the plate electrode region 6 within the deep trench. The semiconductor film 7 includes at least one element of either silicon or germanium (Ge). The semiconductor film 7 is made of one of a polycrystalline semiconductor material film, an amorphous semiconductor material film and a compound complex film of the polycrystalline semiconductor material film and the amorphous semiconductor material film due to annealing hysteresis. The semiconductor film 7 may be either an intrinsic semiconductor or a semiconductor of the same conductivity type as the plate electrode region 6. If the semiconductor film 7 is not an intrinsic semiconductor, it is of the same n-type conductivity as the plate electrode region 6. A dopant may be arsenic (As) or phosphorus (P). The difference between the maximum and the minimum film thickness of the semiconductor film 7 is about 1 nm or less. The semiconductor film 7 is formed between the plate electrode region 6 and the high dielectric constant material film 8, so that the plate electrode region 6 is not in contact with the high dielectric constant material film 8. The semiconductor film 7 will serve as a capacitor/insulator film if it is an intrinsic semiconductor. In contrast, it will serve as a plate electrode if it is of an n-type conductivity. The plate electrode region 6 is buried in and along an inter face of a trench cut in a silicon substrate 1, and the high dielectric constant material film 8 is buried in the trench so as to cover interior face of the plate electrode region 6.

The high dielectric constant material film 8 is formed on the semiconductor film 7 within the deep trench. The high dielectric constant material film 8 may be an aluminum oxide (Al₂O₃) film.

The electrode 12 is formed on the high dielectric constant material film 8 within the deep trench. The electrode 12 may be made of an n-type polycrystalline silicon. The electrode 12 serves as a charging electrode of the capacitor. When a voltage is applied between the plate electrode region 6 and the electrode 12, so that the electric field intensity in the high dielectric constant material film 7 is 300 MV/m, the density of a leakage -current flowing across the thickness of the high dielectric constant material film 8 is about 1×10⁻² A/m² or less. The electrode 12 is electrically connected to the source and drain regions 15 and 16 within the deep trench.

The collar oxide film 10 is buried in the trench so as to cover an upper portion of the interior face of the trench. The collar oxide film 10 is formed on the ends of the semiconductor film 7 and the high dielectric constant material film 8, within the deep trench. The collar oxide film 10 serves as an electrically-separating film that prevents a parasitic transistor, between the plate electrode region 6 and the source and drain regions 15, from turning on.

The source and drain regions 15 and 16 are formed in the silicon substrate 1 including the surface thereof. The source and drain regions 15 and 16 are buried at the top surface of the silicon substrate. The source and drain regions 15 and 16 are impurity diffusion layers. The gate insulating film 13 is formed on the silicon substrate 1. The gate insulating film 13 may be a silicon oxide film. The gate electrode 14 is formed on the gate insulating film 13. The gate insulating film 13 may be an n-type polycrystalline silicon. The silicon substrate 1, the source and drain regions 15 and 16, the gate insulating film 13, and the gate electrode 14 implement a selector transistor.

The semiconductor device according to the first embodiment may be fabricated in the following manner.

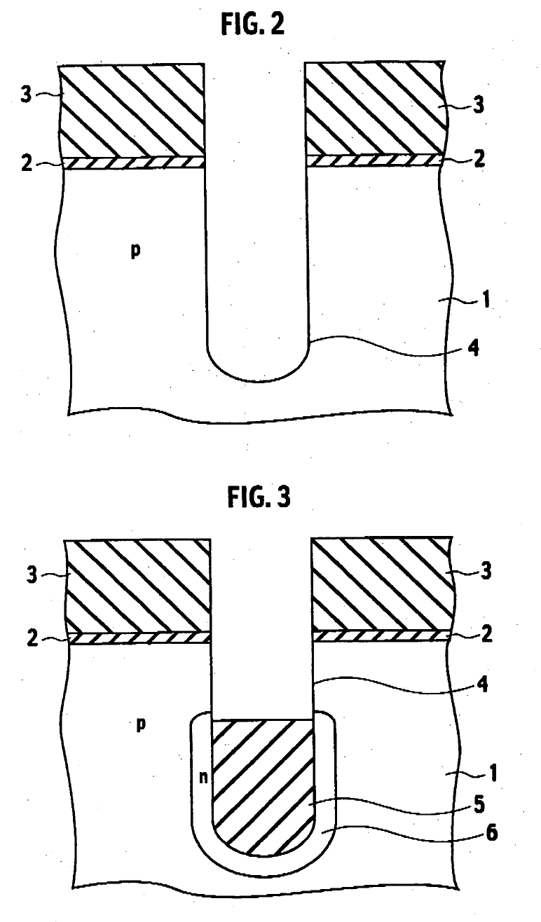

Firstly, as shown in FIG. 2, the p-type silicon single-crystal substrate 1 is prepared. A silicon oxide film 2 is formed on the silicon substrate 1. A silicon nitride film 3 is formed on the silicon oxide film 2. The silicon oxide film 2 and the silicon nitride film 3 are patterned in a deep trench pattern by photolithography. The silicon substrate 1 is selectively etched using the silicon nitride film 3 as a mask, forming a deep trench 4.

As shown in FIG. 3, arsenic glass 5 is buried in a lower part of the deep trench 4. The semiconductor device is subjected to heat treatment, so as to achieve solid state diffusion of arsenic from the arsenic glass 5 to the silicon substrate 1, resulting in formation of the n-type single-crystal plate electrode region 6 in the silicon substrate 1. The arsenic glass 5 is then etched and removed.

As shown in FIG. 4, the semiconductor film 7 is formed across the wafer. The semiconductor film 7 is uniformly formed on the surface of the deep trench 4. As a result, the semiconductor film 7 is deposited on the plate electrode region 6. The semiconductor film 7 is preferably a polycrystal film or an amorphous film including at least one of silicon or germanium. Specifically, the semiconductor film 7 may be a polycrystalline silicon film, an amorphous silicon film, a compound complex film of the polycrystalline semiconductor material film and the amorphous semiconductor material film, a polycrystalline silicon germanium (SiGe) film, an amorphous silicon germanium film, a polycrystal germanium film, an amorphous germanium film, or a stacked film made up of the films thereof. The semiconductor film 7 may be deposited through low-pressure chemical vapor deposition (CVD). V-group elements, such as arsenic or phosphorus, may be added when depositing the film. The thickness of the semiconductor film 7 should be about 20 nm or less, more preferably between about 0.5 nm and about 10 nm, because the thickness of the semiconductor film 7 being at least about 0.5 nm or provides the semiconductor film 7 with localized fluidity when the high dielectric constant material film is subjected to heat treatment. Moreover, the exposed surface area in the deep trench 4 is never too small as long as the thickness of the semiconductor film 7 is about 20 nm or less.

The high dielectric constant material film 8 is overlapped on the semiconductor film 7 across the entire wafer. Also, the high dielectric constant material film 8 is uniformly deposited on the surface of the deep trench 4. The high dielectric constant material film 8 may be Al₂O₃, HfO₂, HfAlO, HfSiO, HfSiON, Ta₂O₅, TiO₂, ZrO₂, La₂O₃, Y₂O₃, barium strontium titanate (BST), strontium titanate (STO), or lead zirconate titanate (PZT) An Al₂O₃ film may be formed through CVD or atomic layer deposition (ALD), for example.

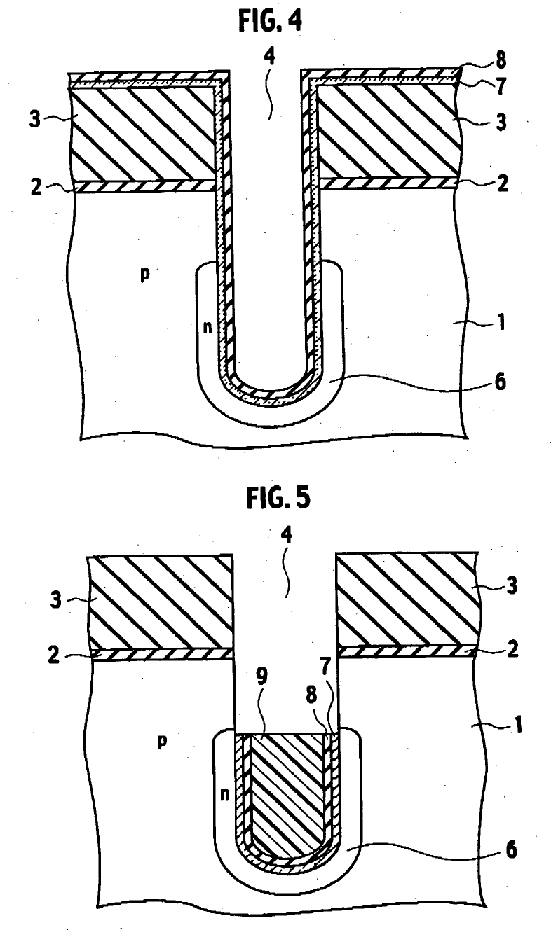

Next, the high dielectric constant material film 8 and the semiconductor film 7 are subjected to heat treatment. The case where the Al₂O₃ film is used as the high dielectric constant material film 8 and a polycrystalline silicon film is used as the semiconductor film 7 is described forthwith. Subjecting the Al₂O₃ film 8 to heat treatment makes it more dense. As shown in FIG. 9, when applying an electric field of 300 MV/m to the Al₂O₃ film B across the thickness thereof, the density of the leakage current flowing across the thickness of the Al₂O₃ film 8 depends on the temperature for the heat treatment. When the temperature for the heat treatment is less than about 700 degrees Centigrade, the leakage current density is greater than 1×10⁻² A/m², and significantly increases as the temperature for the heat treatment decreases. When the temperature for the heat treatment is 700 degrees Centigrade, the leakage current density is about 1×10⁻² A/m². When the temperature for the heat treatment is 800 degrees Centigrade or greater, the leakage current density is about 1×10⁻⁴ A/m². Even when the temperature for the heat treatment is 900 degrees Centigrade, the leakage current density is about 1×10⁻⁴ A/m². When the temperature for the heat treatment is changed from 700 degrees Centigrade to 800 degrees Centigrade, the leakage current density may decrease by two orders of magnitude. When the leakage current density is high, the charge stored in the Al₂O₃ film 8, which becomes a capacitor/insulator film, may leak and cause a problem during a device operation. Therefore, the temperature for the heat treatment should be 700 degrees Centigrade or greater, more preferably 800 degrees Centigrade or greater.

The Al₂O₃ film 18 shrinks as it becomes more dense when subjected to heat treatment. Especially when the Al₂O₃ film 8 is directly formed on the silicon substrate 1 without the semiconductor film 7 therebetween, mechanical stress is applied to the Al₂O₃ film 8 within the deep trench, which has created defects. In this occurs, there has been a case where a large amount of leakage current has flowed via the defects and the Al₂O₃ film 8, serving as a capacitor/insulator film, could not be charged.

However, even though heat treatment of the polycrystalline silicon film 7 between the Al₂O₃ film 8 and the silicon substrate 1 causes the Al₂O₃ film 8 to shrink, mechanical stress on the Al₂O₃ film 8 can be relaxed because the heat treatment also causes the polycrystalline silicon film 7 to crystallize, to provide localized fluidity during crystallization. Therefore, it is possible to prevent defects on the Al₂O₃ film 8. The polycrystalline silicon film 7 is disposed on the interface with the silicon substrate 1 and the Al₂O₃ film 8 so that the silicon substrate 1 is not in contact with the Al₂O₃ film 8. While the first embodiment has described an Al₂O₃ film being applied to the high dielectric constant material film 8, other types of the high dielectric constant material film 8 may provide the same results because they also may shrink after heat treatment.

As shown In FIG. 5, a resist 9 is buried only in the lower part of the deep trench 4. The high dielectric constant material film 8 and the semiconductor film 7 are etched and removed using the resist 9 as a mask. Afterwards, the resist 9 is then removed. As shown in FIG. 6, a collar insulator film 10 is deposited on the exposed region of the silicon substrate 1 within the deep trench 4. As shown in FIG. 7, a resist 11 is buried from the lower part of the deep trench 4 to part of the collar insulator film 10. The exposed region of the collar insulator film 10 is etched and removed using the resist 11 as a mask. The silicon substrate 1 is exposed to an upper part of the deep trench 4. Afterwards, the resist 11 is removed.

As shown in FIG. 8, the charging electrode 12 is buried in the deep trench 4. The charging electrode 12 may be an arsenic-added polycrystalline silicon film. In this manner, manufacture of the capacitor is completed. Lastly, as shown in FIG. 1, the gate insulating film 13 and the gate electrode 14 are deposited. The gate insulating film 13 may be a silicon oxide film. The gate electrode 14 may be an arsenic-added polycrystalline silicon film. The source and drain regions 15 and 16 are formed by self-aligning them with the gate electrode 14. As a result, manufacture of the selector transistor is completed.

According to the first embodiment, a semiconductor device capable of reducing leakage current flowing via the high dielectric constant material film 8 is provided. Moreover, a fabrication method for a semiconductor device capable of reducing leakage current flowing via the high dielectric constant material film 8 is provided.

### Second Embodiment

The first embodiment has described the case where the semiconductor film 7 is disposed between the capacitor/insulator film 8 and the silicon substrate 1 within a deep trench. However, any structure made by forming an insulator film, which shrinks through heat treatment, of the silicon substrate 1 is capable of reducing leakage current flowing through the silicon substrate 1 via the insulator film. The second embodiment describes a case of forming a semiconductor film between the transistor's gate insulating film and the silicon substrate 1. Reduction of leakage current flowing through the silicon substrate 1 via the gate insulating film is possible.

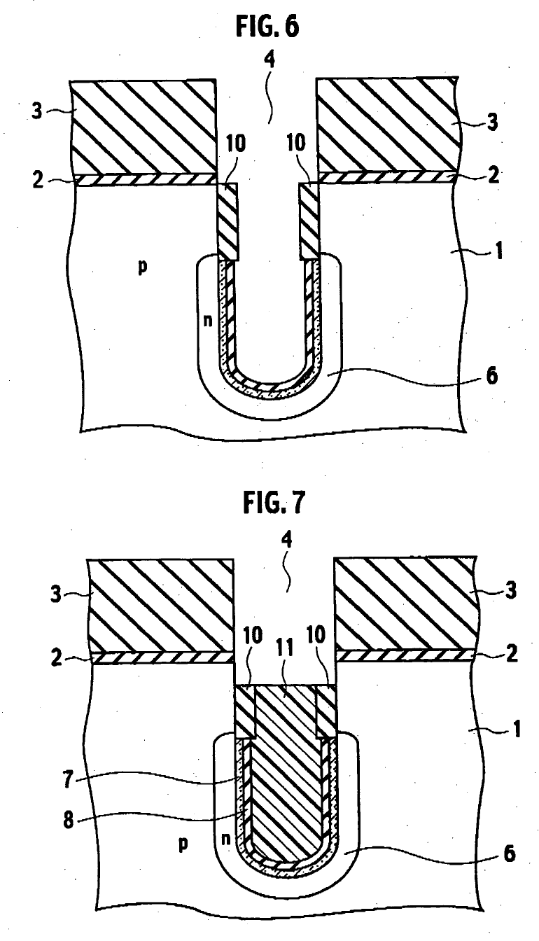

A semiconductor device according to the second embodiment of the present invention comprises a silicon substrate 1, a plate electrode region 6, a semiconductor film 7, a high dielectric constant material film 8, a charging electrode 12, a collar oxide film 10, source and drain regions 15 and 16, a semiconductor film 17, a gate insulating film 18, which is a high dielectric constant material film, and a gate electrode 14, as shown in FIG. 10. The semiconductor device according to the second embodiment is a DRAM that uses a high dielectric constant material film as the capacitor/insulator film 8 and the gate insulating film 18. The DRAM includes a capacitor in a deep trench. In addition, the DRAM includes a selector transistor connected to the capacitor. The semiconductor device according to the second embodiment is different from the semiconductor device according to the first embodiment in that the gate insulating film 18 is a high dielectric constant material film and that the semiconductor film 17 is formed between the gate insulating film 18 and the silicon substrate 1.

The semiconductor film 17 is formed on the silicon substrate 1 and the source and drain regions 15 and 16. The semiconductor film 17 includes at least one of silicon or germanium. The semiconductor film 17 is made of one of a polycrystalline semiconductor material film, an amorphous semiconductor material film and a compound complex film of the polycrystalline semiconductor material film and the amorphous semiconductor material film due to annealing hysteresis. The semiconductor film 17 may be either an intrinsic semiconductor or a semiconductor film of the same conductivity type as the silicon substrate 1. When the semiconductor film 17 is not an intrinsic semiconductor, it is of the same p-type as the silicon substrate 1. A dopant may be boron (B) or indium (In). The difference between the maximum and the minimum film thickness of the semiconductor film 17 is about 1 nm or less. A semiconductor film 17 is formed between the silicon substrate 1 and the high dielectric constant material film 18 so that the silicon substrate 1 is not in contact with the high dielectric constant material film 18.

The high dielectric constant material film 18 is formed between the semiconductor film 17 and the gate electrode 14. The high dielectric constant material film 18 may be made of Al₂O₃, HfO₂, HfAlO, HfSiO, HfSiON, Ta₂O₅, TiO₂, ZrO₂, La₂O₃, Y₂O₃, EST, STO, or PZT. When applying a voltage among the silicon substrate 1, the source and drain regions 15 and 16, and the gate electrode 14 so that the intensity of the electric field within the high dielectric constant material film 18, across the thickness of the film, can be about 300 MV/m, and the density of the leakage current flowing across the thickness of the high dielectric constant material film 18 is about 1×10⁻² A/m² or less.

The semiconductor device according to the second embodiment may be fabricated in the following manner. First, the same capacitor fabrication process of FIGS. 2 through 8, as the process according to the semiconductor device fabrication method of the first embodiment, may be used at the beginning of fabrication.

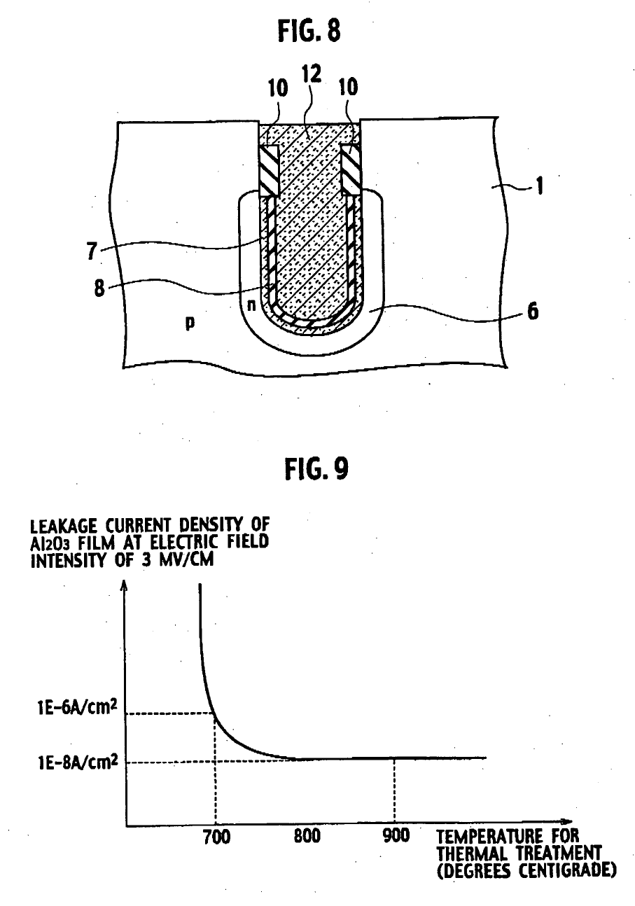

Next, as shown in FIG. 11, the semiconductor film 17 is deposited across a wafer. The semiconductor film 17 is uniformly deposited on the surface of the silicon substrate 1. It is preferable that the semiconductor film 17 be a polycrystalline silicon film, an amorphous silicon film, a compound complex film of the polycrystalline semiconductor material film and the amorphous semiconductor material film, including at least one of silicon or germanium. The semiconductor film 17 may be deposited by low-pressure CVD. III-group elements, such as boron or indium, may be added when depositing the film. The thickness of the semiconductor film 17 should be about 20 nm or less, more preferably between about 0.5 nm and 10 nm, because the thickness of the semiconductor film 17 being in the above range provides the semiconductor film 17 with localized fluidity when the high dielectric constant material film 18 is subjected to a heat treatments. Moreover, when the thickness of the semiconductor film 17 is 20 nm or less, the semiconductor film 17 may be crystallized so that it can be aligned with the crystal lattice of silicon substrate 1 when carrying out heat treatment of the high dielectric constant material film 18.

The high dielectric constant material film 18 is stacked and uniformly deposited on the semiconductor film 17 across the surface of the wafer. Afterwards, the high dielectric constant material film 18 and the semiconductor film 17 are subjected to heat treatment. A case of using an Al₂O₃ film and a polycrystalline silicon film as the high dielectric constant material film 18 and the semiconductor film 17, respectively, is described forthwith. Heat treatment of the Al₂O₃ film 18 makes the film 18 more dense. The Al₂O₃ film 18 shrinks as it becomes denser. Even though subjecting the structure of the polycrystalline silicon film 17, formed between the Al₂O₃ film 18 and the silicon substrate 1, to heat treatment causes the Al₂O₃ film 18 to shrink, mechanical stress on the Al₂O₃ film 18 can be relaxed because the heat treatment also causes the polycrystalline silicon film 17 to crystallize, which allows localized fluidity. As a result, it is possible to prevent defects on the Al₂O₃ film 18, and substantially reduce the same amount of leakage current as with the first embodiment by heat treatment at substantially the same temperature as with the first embodiment. Note that the leakage current in the second embodiment flows through the silicon substrate 1 via the high dielectric constant material film 18. It is also noted that the polycrystalline silicon film 17 is disposed on the interface with the silicon substrate 1 and the Al₂O₃ film 18 so that the silicon substrate 1 is not in contact with the Al₂O₃ film 18. While the second embodiment has described the case where the Al₂O₃ film is applied to the high dielectric constant material film 18, a decrease in leakage current flowing through the silicon substrate 1 via the high dielectric constant material film 18 is possible because other types of high dielectric constant material film 18 also shrink.

Lastly, as shown in FIG. 10, gate electrode 14 is formed on the high dielectric constant material film 18. The gate electrode 14 may be an arsenic-added polycrystalline silicon film. The gate electrode 14 is then patterned. The source and drain regions 15 and 16 are self-aligned with the gate electrode 14. As a result, manufacture of the selector transistor is completed. Note that the second embodiment may be applied to a transistor having a gate insulating film as well as a selector transistor.

According to the second embodiment, a semiconductor device, capable of decreasing leakage current flowing via the high dielectric constant material films 8 and 18, is provided. Moreover, a fabrication method for a semiconductor device, capable of decreasing leakage current flowing via the high dielectric constant material films 8 and 18, is provided.

### Third Embodiment

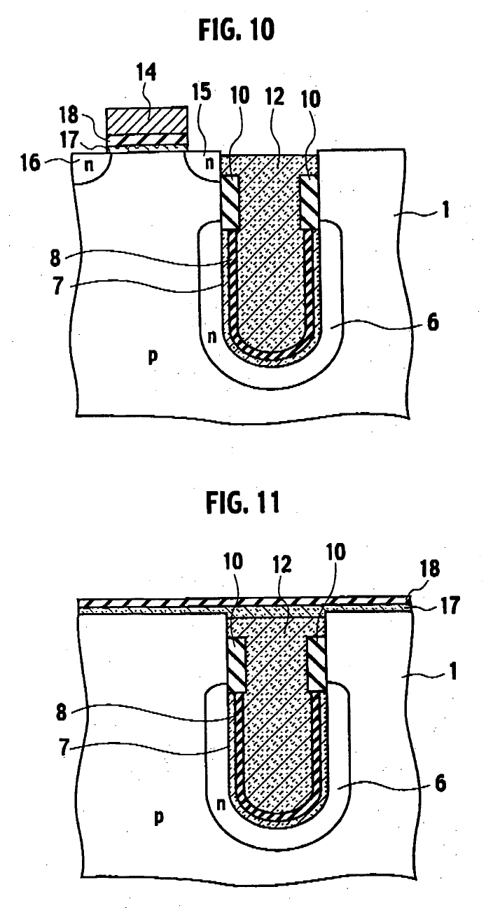

As shown in FIG. 12, the third embodiment discloses a case of forming a semiconductor film 7 between a silicon substrate 1 and an insulator film 8 so that the insulator film 8 can be disposed on the surface of the silicon substrate 1. When forming the insulator film 8, such as a high dielectric constant material film that shrinks through heat treatment, on the silicon substrate 1, the semiconductor film 7 is disposed between the insulator film 6 and the silicon substrate 1, resulting in a decrease of leakage current flowing through the silicon substrate 1 via the insulator film 8.

A semiconductor device according to the third embodiment comprises the silicon substrate 1, the semiconductor film 7, the insulator film 8, and an electrode 12, as shown in FIG. 12, constituting an MIS structure. With the MIS structure, the semiconductor device according to the third embodiment can comprise capacitors and MIS transistors.

The semiconductor film 7 is formed on the silicon substrate 1. The semiconductor film 7 includes at least one element of either silicon or germanium (Ge). The semiconductor film 7 is made of one of a polycrystalline semiconductor material film, an amorphous semiconductor material film and a compound complex film of the polycrystalline semiconductor material film and the amorphous semiconductor material film due to annealing hysteresis. The semiconductor film 7 may be an intrinsic semiconductor or a semiconductor film of the same conductivity type as the silicon substrate 1. The difference between the maximum and the minimum thickness of the semiconductor film 7 is about 1 nm or less. The semiconductor film 7 is formed between the silicon substrate 1 and the insulator film 8 so that the silicon substrate 1 is not in contact with the insulator film 8.

The insulator film 8 is formed between the semiconductor film 7 and the electrode 12. The insulator film 8 may be a high dielectric constant material film, such as Al₂O₃, HfO₂, HfAlO, HfSiO, HfSiON, Ta₂O₅, TiO₂, ZrO₂, La₂O₃, Y₂O₃, BST, STO, or PZT. When applying a voltage between the silicon substrate 1 and the electrode 12 so that the electric field intensity, within the high dielectric constant material film 8 across the thickness of the film, is 300 MV/m, the density of leakage current flowing across the thickness of the insulator film 8 is about 1×10⁻² A/m² or less.

The semiconductor device according to the third embodiment may be fabricated in the following manner.

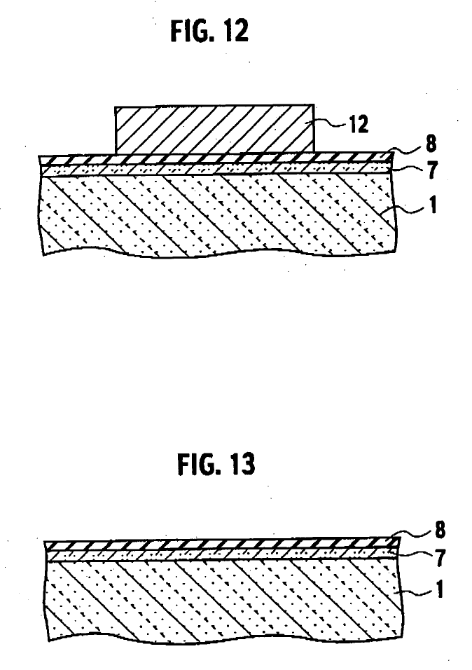

Firstly, as shown in FIG. 13, the semiconductor film 7 is deposited across the wafer, resulting in a uniformly deposited semiconductor film 7 on the surface of the silicon substrate 1. It is preferable that the semiconductor film 7 be a polycrystalline silicon film, an amorphous silicon film, a compound complex film of the polycrystalline semiconductor material film and the amorphous semiconductor material film, including at least one of silicon or germanium. The semiconductor film 7 may be formed by low-pressure CVD. Moreover, a dopant may be added to provide the same conductivity type as the silicon substrate 1 when depositing the film. The thickness of the semiconductor film 7 should be about 20 nm or less, more preferably between about 0.5 nm and 10 nm.

The insulator film 8 is deposited on the semiconductor film 7, resulting in a uniformly deposited film across the wafer. The insulator film 8 and the semiconductor film 7 are then subjected to heat treatment. A case of using an Al₂O₃ film as the insulator film 8 and also using a polycrystalline silicon film as the semiconductor film 7 is described forthwith. The Al₂O₃ film B is subjected to heat treatment, resulting in a more dense film. The Al₂O₃ film 8 shrinks as it becomes more dense. Even though heat treatment of the polycrystalline silicon film 7, between the Al₂O₃ film 8 and the silicon substrate 1, causes the Al₂O₃ film 8 to shrink, the mechanical stress on the Al₂O₃ film 8 can be relaxed because the heat treatment also causes the polycrystalline silicon film 7 to crystallize, which permits localized fluidity during crystallization. Therefore, it is possible to prevent defects on the Al₂O₃ film 8, and substantially reduce the same amount of leakage current as with the first embodiment by heat treatment at substantially the same temperature as with the first embodiment. Note that the leakage current in the third embodiment flows through the silicon substrate 1 via the high dielectric constant material film 8. It is also noted that the polycrystalline silicon film 7 is disposed on the interface with the silicon substrate 1 and the Al₂O₃ film 8 so that the silicon substrate 1 is not in contact with the Al₂O₃ film 8. The third embodiment has described the case where the Al₂O₃ film is applied to the high dielectric constant material film 8. Thus, it is possible to decrease leakage current flowing through the silicon substrate 1, via the high dielectric constant material film 8, because other types of high dielectric constant material film 8 also shrink. Lastly, as shown in FIG. 12, the electrode 12 Is deposited on the insulator film 8. The electrode 12 may be a dopant-added polycrystalline silicon film of the same conductivity type as the silicon substrate 1. The electrode 12 is then patterned, completing the MIS structure.

According to the third embodiment, a semiconductor device capable of decreasing leakage current flowing via the insulator film 8 is-provided. Moreover, a fabrication method for a semiconductor device capable of decreasing leakage current flowing via the insulator film 8 is provided.

### Fourth Embodiment

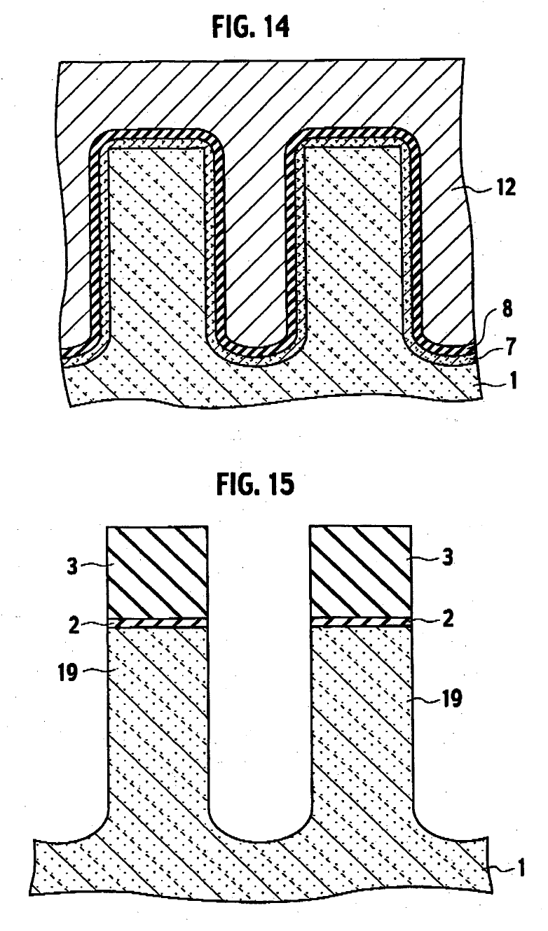

As shown in FIG. 14, the fourth embodiment discloses a case where a semiconductor film 7 is formed between a silicon substrate 1 and an insulator film 8 so that the insulator film 8 can be formed on an uneven surface having protrusions in the silicon substrate 1. In the case of forming an insulator film 8, such as a high dielectric constant material film that shrinks by heat treatment, on the silicon substrate 1, deployment of the semiconductor film 7 between the insulator film 8 and the silicon substrate 1 decreases leakage current flowing through the silicon substrate 1 via the insulator film 8. Note that the protrusion may be columnar, which increases the surface area of the silicon substrate 1. Leakage current will decrease as the area of the insulator film 8, covering silicon substrate 1, increases.

The semiconductor device according to the fourth embodiment comprises the semiconductor film 7, the insulator film 8, an electrode 12, and the silicon substrate 1, as shown in FIG. 14. As such, the semiconductor device according to the fourth embodiment has an MIS structure. With the MIS structure, the semiconductor device, according to the fourth embodiment may comprise capacitors and MIS transistors.

The semiconductor film 7 is formed on the silicon substrate 1. The semiconductor film 7 includes at least one element of either silicon or germanium (Ge). The semiconductor film 7 is made of one of a polycrystalline semiconductor material film, an amorphous semiconductor material film and a compound complex film of the polycrystalline semiconductor material film and the amorphous semiconductor material film due to annealing hysteresis. The semiconductor film 7 may be either an intrinsic semiconductor or a semiconductor film of the same conductivity type as the silicon substrate 1. The difference between the maximum and the minimum thickness of the semiconductor film 7 is about 1 nm or less. The semiconductor film 7 is formed between the silicon substrate 1 and the insulator film 8 so that the silicon substrate 1 is not in contact with the insulator film B.

The insulator film 8 is formed between the semiconductor film 7; and the electrode 12. The insulator film 8 may be a high dielectric constant material film, such as Al₂O₃, HfO₂, HfAlO, HfSiO, HfSiON, Ta₂O₅, TiO₂, ZrO₂, La₂O₃, Y₂O₃, BST, STO, or PZT. When applying a voltage between the silicon substrate 1 and the electrode 12, so that the electric field intensity across the thickness of the high dielectric constant material film 8 is about 300 MV/m, the density of leakage current flowing across the thickness of the insulator film B is about 1×10⁻² A/m² or less.

The semiconductor device according to the fourth embodiment may be fabricated in the following manner.

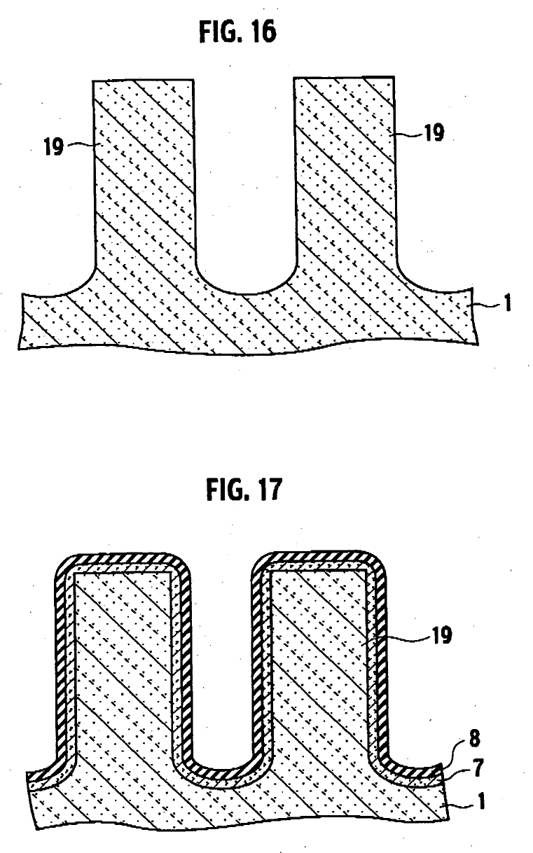

As shown in FIG. 15, a silicon oxide film 2 is deposited on the silicon substrate 1. A silicon nitride film 3 is deposited on the silicon oxide film 2. The silicon oxide film 2 and the silicon nitride film 3 are patterned to be a filmy semiconductor column 19 pattern by photolithography. The filmy semiconductor column 19 is formed by selectively etching the silicon substrate 1 using the silicon nitride film 3 as a mask. As shown in FIG. 16, the silicon oxide film 2 and the silicon nitride film 3 are then removed.

As shown in FIG. 17, the semiconductor film 7 is uniformly deposited across the surface of the silicon substrate 1. It is preferable that the semiconductor film 7 is one of a polycrystal film, an amorphous film and a compound complex film of the polycrystal film and the amorphous film, including at least one of silicon or germanium. More specifically, the semiconductor film 7 may be a polycrystalline silicon film, an amorphous silicon film, a compound complex film of the polycrystalline silicon film and the amorphous silicon film due to annealing hysteresis, a polycrystalline silicon germanium film, an amorphous silicon germanium film, a polycrystalline germanium film, an amorphous germanium film, or a stacked film made of the above films. The semiconductor film 7 may be deposited by low-pressure CVD. In addition, a dopant that provides the same conductivity type as the silicon substrate 1 may be added when depositing the film. The thickness of the semiconductor film 7 should be about 20 nm or less, more preferably between about 0.5 nm and 10 nm.

The insulator film 8 is deposited on the semiconductor film 7, resulting in a uniformly deposited film on the wafer. The insulator film 8 is formed by CVD or ALD when it is an Al₂O₃ film, for example. The insulator film 8 and the semiconductor film 7 are then subjected to heat treatment. A case of using an Al₂O₃ film and a polycrystalline silicon film as the high dielectric constant material film 18 and the semiconductor film 17, respectively, is described forthwith. Heat treatment of the Al₂O₃ film 8 makes the film 8 more dense. The Al₂O₃ film 8 shrinks as the film 8 becomes more dense. Even though subjecting the structure of the polycrystalline silicon film 7, formed between the Al₂O₃ film 8 and the silicon substrate 1, to heat treatment causes the Al₂O₃ film 8 to shrink, the mechanical stress on the Al₂O₃ film 8 can be relaxed because the heat treatment also causes the polycrystalline silicon film 7 to crystallize, which allows localized fluidity. As a result, it is possible to prevent defects on the Al₂O₃ film 8, and substantially reduce the same amount of leakage current as with the first embodiment by heat treatment at substantially the same temperature as with the first embodiment. Note that the leakage current in the fourth embodiment flows through the silicon substrate 1 via the high dielectric constant material film 8. It is also noted that the polycrystalline silicon film 7 is disposed on the interface with the silicon substrate 1 and the Al₂O₃ film 8 so that the silicon substrate 1 is not in contact with the Al₂O₃ film 8. Lastly, the electrode 12 is formed on the insulator film 8 as shown in FIG. 14. The electrode 12 may be a dopant-added polycrystalline silicon film of the same conductivity type as the silicon substrate 1. This completes manufacture of the MIS structure.

According to the fourth embodiment, a semiconductor device capable of reducing leakage current flowing via the insulator film 8 is provided Moreover, a fabrication method for a semiconductor device capable of reducing leakage current flowing via the insulator film 8 is provided.

### Fifth Embodiment

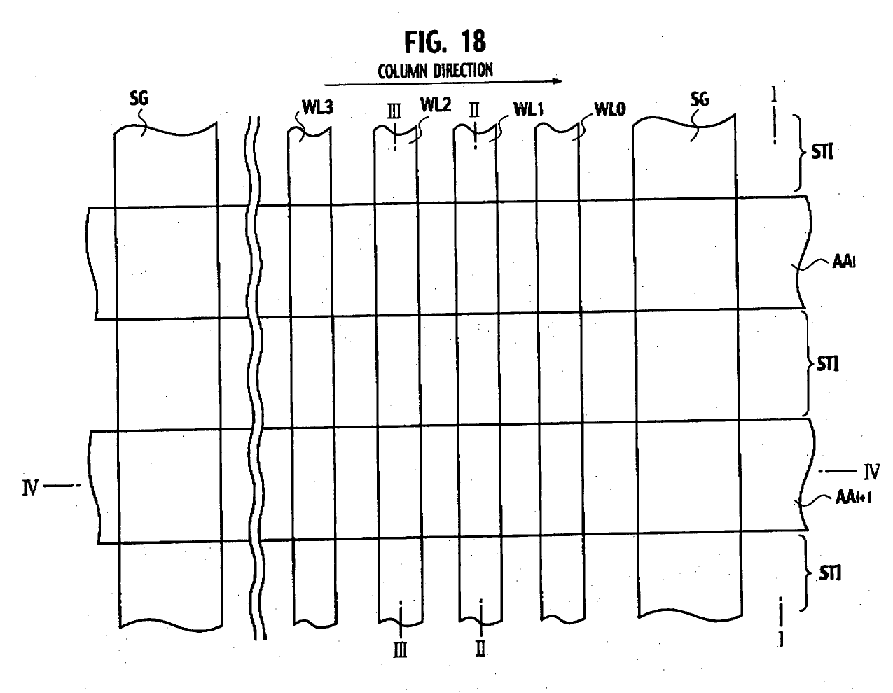

In a schematic top plan view pattern diagram of a nonvolatile semiconductor memory with a NAND-type EEPROM structure as a fifth embodiment of the present invention, as shown in FIG. 18, memory cell transistors with a stacked gate structure are disposed in active regions AAᵢ and AAᵢ₊₁ sandwiched between device isolating regions such as shallow trench isolations (STIs). The serially connected memory cell transistors have select gate transistors each connected to a select gate line SG disposed at the ends of a NAND memory cell unit. In addition, the control gate of each memory cell transistor is connected to a corresponding one of word lines WL0, WL1, WL2, WL3, . . . .

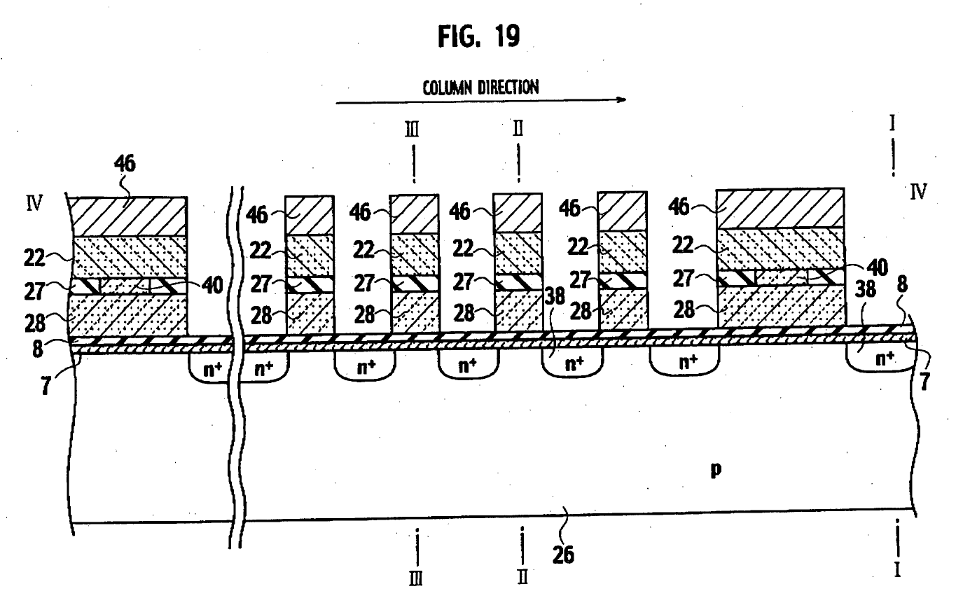

FIG. 19, which is a schematic device cross-sectional structure cut along the line IV-IV of FIG. 18, shows memory cell transistor areas and select gate transistor areas of a NAND-type serial structure. In the top plan view pattern diagram of FIG. 18, the lines I-I, II-II, and III-III correspond to the lines I-I, II-II, and III-III in FIG. 19, respectively.

Each NAND-type memory cell transistor area includes diffusion layers 38 formed in a p-well region or a semiconductor substrate 26, a semiconductor film 7, a high dielectric constant material film 8, which acts as a tunneling insulator film, formed on the p-well or the semiconductor substrate 26, a floating gate 28, which is disposed on the semiconductor film 7 and the high dielectric constant material film 8, a control gate 22, which is disposed on the floating gate 28 via an inter-gate insulator film 27 such as an alumina film, and a salicide film 46, which is disposed on the control gate 22.

Each select gate transistor area includes diffusion layers 38 formed in a p-well region or a semiconductor substrate 26, a semiconductor film 7 and a high dielectric constant material film 8 formed on the p-well or the semiconductor substrate 26, a floating gate 28, which is disposed on the the semiconductor film 7 and the high dielectric constant material film 8, a control gate 22, which is disposed on the floating gate 28 via a polysilicon contact 40 formed in an inter-gate insulator film 27, and a salicide film 46, which is disposed on the control gate 22. In other words, in the select gate transistor area, the floating gate 28 and the control gate 22 are short-circuited via the polysilicon contact 40.

The formation methods for the gate electrode of the select gate transistor of the fifth embodiment, include methods of providing a conducting connection between the floating gates 28 and the control gates 22 by removing, through etching, a part of the inter-gate insulator film 27 of the select gate transistor.

The semiconductor film 7 is formed on the p-well or the semiconductor substrate 26 and the diffusion layers 38. The semiconductor film 7 includes at least one of silicon or germanium. The semiconductor film 7 is made of one of a polycrystalline semiconductor material film, an amorphous semiconductor material film and a compound complex film of the polycrystalline semiconductor material film and the amorphous, semiconductor material film due to annealing hysteresis. The semiconductor film 7 may be either an intrinsic semiconductor or a semiconductor film of the same conductivity type as the p-well or the semiconductor substrate 26. When the semiconductor film 7 is not an intrinsic semiconductor, it is of the same p-type as the p-well or the semiconductor substrate 26. A dopant may be boron (B) or indium (In). A semiconductor film 7 is formed between the p-well or the semiconductor substrate 26 and the high dielectric constant material film 8 so that the p-well or the semiconductor substrate 26 is not in contact with the high dielectric constant material film 8.

The high dielectric constant material film 8 is formed between the semiconductor film 7 and the floating gate 28. The high dielectric constant material film 8 may be made of Al₂O₃, HfO₂, HfAlO, HfSiO, HfSiON, Ta₂O₅, TiO₂, ZrO₂, La₂O₃, Y₂O₃, BST, STO, or PZT. When applying a voltage among the p-well or the semiconductor substrate 26, the diffusion layers 38, and the floating gate 28 so that the intensity of the electric field within the high dielectric constant material film 8, across the thickness of the film, can be about 300 MV/m, and the density of the leakage current flowing across the thickness of the high dielectric constant material film 8 is about 1×10² A/m² or less.

The semiconductor device according to the fifth embodiment may be fabricated in the following manner As shown in FIG. 19, the semiconductor film 7 is deposited across a wafer. The semiconductor film 7 is uniformly deposited on the p-well or the semiconductor substrate 26. It is preferable that the semiconductor film 7 may be made of a polycrystalline silicon film, an amorphous silicon film, a compound complex film of the polycrystalline semiconductor material film and the amorphous semiconductor material film, including at least one of silicon or germanium. The semiconductor film 7 may be deposited by low-pressure CVD. III-group elements, such as boron or indium, may be added when depositing the film. The thickness of the semiconductor film 7 should be about 20 nm or less, more preferably between about 0.5 nm and 10 nm, because the thickness of the semiconductor film 7 being in the above range provides the semiconductor film 7 with localized fluidity when the high dielectric constant material film 8 is subjected to a heat treatment. Moreover, when the thickness of the semiconductor film 7 is 20 nm or less, the semiconductor film 7 may be crystallized so that it can be aligned with the crystal lattice of the p-well or the semiconductor substrate 26 when carrying out heat treatment of the high dielectric constant material film 8.

The high dielectric constant material film 8 is stacked and uniformly deposited on the semiconductor film 7 across the surface of the wafer. Afterwards, the high dielectric constant material film 8 and the semiconductor film 7 are subjected to heat treatment. A case of using an Al₂O₃ film and a polycrystalline silicon film as the high dielectric constant material film 8 and the semiconductor film 7, respectively, is described forthwith. Heat treatment of the Al₂O₃ film 8 makes the film 8 more dense. The Al₂O₃ film 8 shrinks as it becomes denser. Even though subjecting the structure of the polycrystalline silicon film 7, formed between the Al₂O₃ film 8 and the p-well or the semiconductor substrate 26, to heat treatment causes the Al₂O₃ film 8 to shrink, mechanical stress on the Al₂O₃ film 8 can be relaxed because the heat treatment also causes the polycrystalline silicon film 7 to crystallize, which allows localized fluidity. As a result, it is possible to prevent defects on the Al₂O₃ film 8, and substantially reduce the same amount of leakage current as with the first embodiment by heat treatment at substantially the same temperature as with the first embodiment.

Note that the leakage current in the fifth embodiment flows through the p-well or the semiconductor substrate 26 via the high dielectric constant material film B. It is also noted that the polycrystalline silicon film 7 is disposed on the interface with the p-well or the semiconductor substrate 26 and the Al₂O₃ film 8 so that the p-well or the semiconductor substrate 26 is not in contact with the Al₂O₃ film 8. While the fifth embodiment has described the case where the Al₂O₃ film is applied to the high dielectric constant material film 8, a decrease in leakage current flowing through the p-well or the semiconductor substrate 26 via the high dielectric constant material film 8is possible because other types of high dielectric constant material film 8 also shrink.

As shown in FIG. 19, the floating gate 28 is formed on the high dielectric constant material film 8. The floating gate 28 may be an arsenic-doped polycrystalline silicon film. The inter-gate insulator film 27 is formed on the floating gate 28. Then, the inter-gate insulator film 27 is patterned to form a contact hole for the polysilicon contact 40 of the select gate transistor. Then, the control gate 22 is formed on the inter-gate insulator film 27. In the select gate transistor area, the floating gate 28 and the control gate 22 are short-circuited via the polysilicon contact 40.

The control gate electrode 22 and the floating gate electrode 28 are then patterned. Then, the salicide film 46 is formed on the control gate 22. The diffusion layers 38 are self-aligned with the stacked gate structure of the gate electrodes 22 and 28.

As a result, manufacture of the nonvolatile semiconductor memory with a NAND-type EEPROM structure is completed.

According to the fifth embodiment, a semiconductor device, capable of decreasing leakage current flowing via the high dielectric constant material films 8, is provided. Moreover, a fabrication method for a semiconductor device, capable of decreasing leakage current flowing via the high dielectric constant material films 8, is provided.

### Other Embodiments

The present invention is not limited to the first to the fifth embodiment. According to the first to the fourth embodiment, the silicon substrate 1 should be a semiconductor film substrate. According to the fifth embodiment, the p-well or the semiconductor substrate 26 should be a semiconductor film well or substrate.

The semiconductor film well or substrate may be a silicon-on-insulator (SOI) substrate's silicon layer, a film of a silicon germanium (SiGe) alloy semiconductor, or a film of a silicon germanium carbide (SiGeC) alloy semiconductor.

Moreover, a variety of modifications of the embodiments are possible as long as they do not deviate from the scope of the claimed invention.

The present invention may be embodied in other specific forms without departing from the spirit or essential characteristics thereof.

Note that the structure of the memory cell transistor of the fifth embodiment may be applied to another type nonvolatile semiconductor memory, such as NOR, AND, two-transistor/cell, three transistor/cell structures.

The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

What is claimed is:

1. A semiconductor device comprising:
a plate electrode region made of a single-crystal silicon;
a semiconductor film made of one of a polycrystal, an amorphous and a compound complex of the polycrystal and the amorphous, arranged on the plate electrode region, the semiconductor film including at least one of silicon and germanium;
a high dielectric constant material film formed on the semiconductor film; and
an electrode formed on the high dielectric constant material film.

2. The semiconductor device of claim 1, wherein, when an electric field intensity within the high dielectric constant material film is about 300 MV/m, density of leakage current flowing across the thickness of the high dielectric constant material film is about 1×10⁻² A/m² or less.

3. The semiconductor device of claim 1, wherein, a difference between a maximum and a minimum thickness of the semiconductor film is about 1 nm or less.

4. The semiconductor device of claim 1, wherein the high dielectric constant material film is an oxide film including aluminum.

5. The semiconductor device of claim 1, wherein the plate electrode region is buried in and along an interior face of a trench cut an a silicon substrate, and the high dielectric constant material film is buried in the trench so as to cover interior face of the plate electrode region.

6. The semiconductor device of claim 1, wherein the semiconductor film is formed on the surface of a silicon substrate.

7. The semiconductor device of claim 1, wherein the semiconductor film is formed on an uneven surface of a silicon substrate.

8. The semiconductor device of claim 5, further comprising;
a collar oxide film buried in the trench so as to cover an upper portion of the interior face of the trench, formed on ends of the semiconductor film and the high dielectric constant material film, the electrode is buried in the trench so as to cover the collar oxide and the high dielectric constant material film;
a source region contacted with the electrode and buried at a top surface of the silicon substrate;
a drain region buried at the top surface of the silicon substrate;
a gate insulating film formed on the top surface of the silicon substrate between the source region and the drain region; and
a gate electrode formed on the gate insulating film.

9. The semiconductor device of claim 1, wherein the semiconductor film and the plate electrode region are of the same conductivity type.

10. The semiconductor device of claim 1, wherein the thickness of the semiconductor film is between about 0.5 nm and 20 nm.

11. A semiconductor device fabrication method comprising:
depositing a semiconductor film made of one of a polycrystal, an amorphous and a compound complex of the polycrystal and the amorphous, the semiconductor film including at least one of silicon and germanium on a single-crystal silicon region;
depositing a high dielectric constant material film on the semiconductor film;
annealing the high dielectric constant material film at a temperature of 700 degrees Centigrade or greater; and
depositing an electrode film on the high dielectric constant material film.

12. The method of claim 11, wherein a difference between a maximum and a minimum thickness of the semiconductor film is about 1 nm or less.

13. The method of claim 11, wherein the high dielectric constant material film is an oxide film including aluminum.

14. The method of claim 11, wherein the silicon region is formed to include the surface of a trench formed in a silicon substrate.

15. The method of claim 11, wherein the semiconductor film is formed on an uneven surface of a silicon substrate including a protrusion.

16. The method of claim 11, wherein the semiconductor film and the silicon region are the same conductivity type.

17. The method of claim 11, wherein the thickness of the semiconductor film is between about 0.5 nm and 20 nm.

18. The method of claim 11, wherein the annealing shrinks the semiconductor film and the high dielectric constant material film.

19. The method of claim 11, wherein the annealing crystallizes the semiconductor film.

20. A semiconductor device having a stacked gate structure comprising:
a semiconductor film made of one of a polycrystal, an amorphous and a compound complex of the polycrystal and the amorphous, the semiconductor film including at least one of silicon and germanium;
a high dielectric constant material film formed on the semiconductor film:
a floating gate electrode formed on the high dielectric constant material film;
an inter-gate insulator film formed on the a floating gate electrode; a control gate electrode formed on the inter-gate insulator layer.
